(19) United States
(12) Patent Application Publication
(10) Pub. No.: US 2026/0106628 A1
(43) Pub. Date: Apr. 16, 2026

(54) REFERENCE-LESS LEVEL-CROSSING ADC WITH A BUMP-BASED ADAPTIVE-BIAS COMPARATOR

(71) Applicant: IMEC VZW, Leuven (BE)

(72) Inventors: Xiaolin Yang, Leuven (BE); Xiaonan Xing, Leuven (BE); Chutham Sawigun, Leuven (BE); Carolina Mora Lopez, Heverlee (BE)

(21) Appl. No.: 19/356,881

(22) Filed: Oct. 13, 2025

(30) Foreign Application Priority Data
Oct. 16, 2024 (EP) 24206837.7

(51) Int. Cl. H03M 3/02

(52) U.S. Cl. CPC H03M 3/02

(57) ABSTRACT

An ADC circuit with a comparator circuit for a neural interface is provided. The comparator circuit includes a comparator to receive a first and a second signal, and amplify the first and the second signal. A bump bias circuit of the comparator circuit receives the amplified first and second signal, and causes the comparator to operate at a higher power level when a difference between the amplified first and second signal is smaller and to operate at a lower power level when the difference between the amplified first and second signal is larger. Two comparator circuits are connected to a first and second switching circuit. A control circuit of the ADC circuit may set a capacitor state of first capacitor pairs of the first switching circuit and a capacitor state of second capacitors pairs of the second switching circuit, based on outputs of the first and second comparator circuit.

### CROSS-REFERENCE TO RELATED APPLICATIONS

The present application is a non-provisional patent application claiming priority to European Patent Application No. 24206837.7, filed Oct. 16, 2024, the contents of which are hereby incorporated by reference.

### FIELD OF THE DISCLOSURE

The present disclosure relates to comparators and analog-to-digital converters (ADCs), for example, suitable for a neural interface. A level-crossing (LC) based ADC circuit for a neural interface is provided. The ADC circuit may include at least one comparator circuit that has a bump bias circuit. Further, a method of operating the LC based ADC circuit is provided.

### BACKGROUND

A large-scale neural interface is a system designed to facilitate extensive recordings from hundreds, or even thousands, of individual neurons simultaneously. This technology provides a way for neuroscience to better understand the inner workings of the brain.

An ADC is useful in such systems and is used to periodically sample and convert neural signals for data transmission and post-processing. The ADC may have a sampling rate of tens of thousands of samples per second for each recording site. Hence, with increased recording density, data transmission or processing may be challenging. One approach is to facilitate a LC ADC, which converts a neural signal (e.g., only) when a specific neural event, such as a spike, happens. Unlike a continuous-sampling ADC, which can generate massive amounts of data even when the neural activity is sparse, the LC ADC operates on a “sample-on-change” principle. It (e.g., only) records data when there is a meaningful change in the signal, hence, it reduces the overall data volume.

To achieve (e.g., relatively) low power consumption, a fixed-threshold-window LC ADC may be used. A LC ADC (e.g., continuously) tracks an input signal through a fixed threshold window, which is created by two voltages V_{H} (high) and V_{L} (low). An input representation of the quantized digital output D_{OUT} is fed back through a digital-to-analog converter (DAC) and subtracted from the analog input V_{IN}. The residue voltage VRES is the quantization error, which is then compared against two voltage thresholds V_{H} and V_{L} by upper or lower zero-crossing detectors (ZCD). When VRES exceeds this comparison interval, the corresponding ZCD triggers an update, and the up-down counter either increments or decrements, causing the DAC output to shift up or down by a voltage value Vₜₕ (wherein it is assumed that Vₜₕ is equal to V_{H}-V_{L}), so that the residue VRES is again maintained within the comparison interval (between V_{H} and V_{L}). Therefore, the LC ADC generates a digital output (e.g., only) when a crossing or an event happens, which leads to a non-uniform sampling and conversion. FIG. 13B shows an example of a waveform (digital output D_{OUT}) of the LC ADC of FIG. 13A in comparison with the analog input V_{IN}.

The voltage thresholds created by V_{H} and V_{L} are crucial to the performance of the LC ADC. An extra voltage generator is, however, used to generate these voltages. Moreover, a mismatch between V_{H}-V_{L} and Vₜₕ will degrade the performance of the LC ADC. An extra on-chip circuit or an off-chip fine trimmer may be used to generate the voltages V_{H} or V_{L} to eliminate this. However, both cause hardware complexity. Moreover, to continuously monitor the change of the residue voltage VRES, the comparators should be always-on, so that the comparators consume a static bias current for a fast decision once a crossing happens. This results in overall high power consumption even if there is no event.

### SUMMARY

In view of the above, the present disclosure is to provide an ADC circuit for a neural interface, which is able to operate based on LC. The ADC circuit uses no additional voltage generators, and the hardware should be less complex than at least one conventional LC ADC for a neural interface. The present disclosure also equips the LC ADC circuit with at least one comparator circuit that has a low power consumption.

The disclosure described herein relates to the independent claims as well as additional implementations described in the dependent claims.

A first aspect of this disclosure provides an ADC circuit for a neural interface, wherein the ADC circuit is configured to receive a differential input signal comprising a first signal and a second signal. The ADC circuit comprises a first comparator circuit and a second comparator circuit. An inverting input of the first comparator circuit and a non-inverting input of the second comparator circuit are connected to a common mode voltage of the first signal and the second signal. The ADC circuit further includes a first switching circuit configured to receive the first signal and to output a modified first signal via a first voltage line to a non-inverting input of the first comparator circuit, a second switching circuit configured to receive the second signal as an input and to provide a modified second signal via a second voltage line to an inverting input of the second comparator circuit, and a control circuit, wherein an output of each comparator circuit is connected as input to the control circuit. The first switching circuit comprises a plurality of first capacitor pairs, and the second switching circuit comprises a plurality of second capacitor pairs. The first and the second capacitor pairs are (e.g., respectively) arranged one after the other along the first voltage line and the second voltage line, and are (e.g., respectively) connected with a common node to the first voltage line and the second voltage line. The control circuit is configured to set at least one capacitor state of the first capacitor pairs and at least one capacitor state of the second capacitors pairs based on the outputs of the first comparator circuit and the second comparator circuit.

To eliminate or reduce usage of voltage thresholds—as used (e.g., required) in a conventional LC ADC—a pre-switching concept is introduced, such as by adding the first and the second switching circuit. For example, these switching circuits may deviate the input signals by a certain voltage value, under the control of the control circuit. The control circuit may be a control DAC. Since no voltage thresholds are used, additional voltage generators may also be omitted. Further, also an extra on-chip circuit and/or an off-chip fine trimmer for such voltage values may be omitted. Thus, hardware complexity of the LC ADC circuit, as provided herein, is minimized (e.g., low).

Herein, a comparator circuit—such as the first comparator circuit or the second comparator circuit—may include a comparator, or may include a comparator and additional circuitry connected to the comparator.

The differential input signal may be a differential voltage signal, i.e., the first signal and the second signal are voltage signals, e.g., of varying voltage value. Also, the modified signals and the internally amplified signals may be voltage signals.

In an example embodiment of the ADC circuit, the control circuit is configured to (e.g., initially) set each capacitor state to a default value.

In an example embodiment of the ADC circuit, the control circuit is configured to change at least one capacitor state of the first capacitor pairs, such that a predetermined voltage value is subtracted from the modified first signal when the second signal is smaller than the common mode voltage, and such that the predetermined voltage value is added to the modified first signal when the second signal is larger than the common mode voltage.

In an example embodiment of the ADC circuit, when the output of the first comparator circuit switches “up” from a low state to a high state, while the output of the second comparator circuit stays at a high state, the control circuit is configured to change at least one capacitor state of the first capacitor pairs such that the predetermined voltage value is subtracted from the modified first signal, and to change at least one capacitor state of the second capacitor pair such that the predetermined voltage value is added to the modified second signal. When the output of the first comparator circuit switches “down” from a high state to a low state, while the output of the second comparator circuit stays at a low state, the control circuit is configured to change at least one capacitor state of the first capacitor pairs such that the predetermined voltage value is added to the modified first signal, and to change at least one capacitor state of the second capacitor pairs such that the predetermined voltage value is subtracted from the modified second signal.

In an example embodiment of the ADC circuit, when the output of the second comparator circuit switches “down” from a high state to a low state, the control circuit is configured to change at least one capacitor state of the first capacitor pairs such that twice the predetermined voltage value is added to the modified first signal. When the output of the second comparator circuit switches “up” from a low state to a high state, the control circuit is configured to change at least one capacitor state of the first capacitor pairs such that twice the predetermined voltage value is subtracted from the modified first signal.

In an example embodiment of the ADC circuit, the ADC circuit further comprises an up-down counter, which is configured to receive from the control circuit an output signal and an indication of “up” or “down” switch of a comparator circuit output, and is configured to output a cumulated signal based on the output signal and indication received from the control circuit.

In an example embodiment of the ADC circuit, the first comparator circuit comprises a first comparator configured to internally amplify the modified first signal and the common mode voltage (e.g., respectively), and a first bump bias circuit configured to receive the amplified modified first signal and the amplified common mode voltage. The first bump bias circuit is further configured to cause the first comparator to operate at a higher power level when a difference between the amplified modified first signal and the amplified common mode voltage is smaller, and operate at a lower power level when the difference between the amplified modified first signal and the amplified common mode voltage is larger.

In an example embodiment of the ADC circuit, the second comparator circuit comprises a second comparator configured to internally amplify the modified second signal and the common mode voltage (e.g., respectively), and a second bump bias circuit configured to receive the amplified modified second signal and the amplified common mode voltage. The second bump bias circuit is further configured to cause the second comparator to operate at a higher power level when a difference between the amplified modified second signal and the amplified common mode voltage is smaller, and operate at a lower power level when the difference between the amplified modified second signal and the amplified common mode voltage is larger.

For example, both the first comparator circuit and the second comparator circuit may be integrated with a (e.g., respective) bump bias circuit, as described herein. The modified first signal and the common mode voltage are a first differential input signal for the first comparator circuit, whereas the common mode voltage and the modified second signal are a second differential input signal for the second comparator circuit. The non-inverting input and inverting input of a comparator circuit may relate to a non-inverting input and inverting input of a comparator of the comparator circuit. The first comparator circuit will operate in the higher power mode when the difference between the amplified modified first signal and the amplified common mode voltage is smaller, and the second comparator circuit will operate in the higher power mode when the difference between the amplified modified second signal and the amplified common mode voltage is smaller.

A comparator circuit having the bump bias circuit can operate with a low power consumption. For example, to achieve a reduced power consumption compared to a conventional comparator, the bump bias circuit is integrated with the comparator of the comparator circuit (e.g., the comparator may be a (e.g., conventional) comparator, except that it is connected to the bump bias circuit in the manner described). The bump bias circuit is used to monitor the amplified versions of the input signals, which may be voltage signals, such as the amplified modified first or second signal and the amplified common mode voltage. When the amplified signals are closer together, the bump bias circuit may operate to set the comparator to the higher power mode. Conversely, when the amplified signals are less close together (i.e., more different from each other), the bump bias circuit may tend to set the comparator into the lower power mode, which saves power. The current consumption is thus (e.g., significantly) lower than for a conventional constant bias comparator.

In an example embodiment of the ADC circuit, the first and/or second bump bias circuit is configured to provide a larger supply current to (e.g., respectively) the first or second comparator when the difference between (e.g., respectively) the amplified modified first or second signal and the common mode voltage is smaller, and provide a smaller supply current to (e.g., respectively) the first or second comparator when the difference between (e.g., respectively) the amplified modified first or second signal and the amplified common mode voltage is larger.

The first bump bias circuit relates to the first comparator and the amplified modified first signal, and the second bump bias circuit relates to the second comparator and the amplified modified second signal.

The bump bias circuit may comprise circuitry that receives the (e.g., respective) internally amplified signals as input, and provides the supply current in dependence of the difference between the amplified signals as output. This may be achieved with, for example, a variety of transistors and/or transistor pairs, but is not limited thereto. For example, the supply current may be mirrored back through a current mirror to the comparator. The larger supply current maintains or transitions the comparator into the higher power mode, while the lower supply current maintains or transitions the comparator into the lower power mode, to (e.g., significantly) save power. In this disclosure, the comparator's power mode may accordingly depend on the supply current provided to the comparator.

In an example embodiment of the ADC circuit, the first and/or second bump bias circuit is configured to provide a (e.g., continuously) increasing supply current to (e.g., respectively) the first or second comparator when a difference between (e.g., respectively) the amplified modified first or modified signal and the amplified common mode voltage (e.g., continuously) decreases.

In an example embodiment of the ADC circuit, the first and/or second bump bias circuit (e.g., respectively) comprises a first transistor pair comprising a first transistor, a second transistor, and a second transistor pair comprising a third transistor and a fourth transistor. A source of the first transistor is connected to a drain of the second transistor. A source of the third transistor is connected to a drain of the fourth transistor. A source of the second transistor and a source of the fourth transistor are connected to ground. A drain of the first transistor and a drain of the third transistor are connected to a common node, to which also a current output transistor is connected. The amplified modified first or second signal (e.g., respectively) is connected to a gate of the first transistor and a gate of the fourth transistor. The common mode voltage is connected to a gate of the second transistor and a gate of the third transistor. The current output transistor is configured to output a larger supply current to (e.g., respectively) the first or second comparator when the difference between (e.g., respectively) the amplified modified first or second signal and the amplified common mode voltage is smaller, and output a smaller supply current to (e.g., respectively) the first or second comparator when the difference between (e.g., respectively) the amplified modified first or second signal and the amplified common mode voltage is larger.

This provides an example embodiment of the above-mentioned circuitry of the bump bias circuit. The example bump bias circuit with the various transistors may be integrated with the (e.g., transistors of the) comparator to maintain a low hardware complexity. Again, the first bump bias circuit may relate to the first comparator and the amplified modified first signal, while the second bump bias circuit may relate to the second comparator and the amplified modified second signal.

In an example embodiment of the ADC circuit, a source of the current output transistor is connected to a supply voltage, a drain of the current output transistor is connected to the common node, and a gate of the current output transistor is connected to the drain of the current output transistor and to the comparator.

In an example embodiment of the ADC circuit, the gate of the current output transistor is connected to a gate of a current input transistor of (e.g., respectively) the first or second comparator. The current output transistor and the current input transistor form a current mirror.

For example, the supply current may be mirrored back through the current mirror to the comparator, and may set or transition the comparator into a higher power mode or lower power mode (e.g., respectively).

In an example embodiment of the ADC circuit, wherein the first and/or second comparator circuit is configured to perform an auto-zeroing operation to calibrate the first and/or second bump bias circuit, such that the first and/or second bump bias circuit is configured to cause (e.g., respectively) the first or second comparator to operate at a maximum power level when the amplified modified first or second signal is equal to the amplified common mode voltage.

A mismatch across the transistors of the bump bias circuit may introduce an offset, which may shift the zero-crossing point of the feedback signal (e.g., supply current) to the comparator to an offset voltage. To mitigate this, the offset calibration—i.e., the auto-zeroing operation—may be performed before the comparator circuit's normal operation. In this way, for example, it may be achieved that the largest supply current is fed back to the comparator, if the amplified input signals to the comparator are equal.

The first comparator circuit relates to the first bump bias circuit, the first comparator, and the amplified modified first signal, while the second comparator circuit relates to the second bump bias circuit, the second comparator, and the amplified modified second signal

A second aspect of this disclosure provides a method of operating an ADC circuit for a neural interface. The ADC circuit, such as the one shown in FIG. 13A, comprises a first comparator circuit, a second comparator circuit, a first switching circuit, a second switching circuit, and a control circuit. The method comprises receiving a differential input signal comprising a first signal and a second signal, receiving the first signal with the first switching circuit and providing a modified first signal via a first voltage line to a non-inverting input of the first comparator circuit; receiving the second signal with the second switching circuit and providing a modified second signal via a second voltage line to an inverting input of the second comparator circuit, providing a common mode voltage of the first signal and the second signal to an inverting input of the first comparator circuit and to a non-inverting input of the second comparator circuit, and setting, by the control circuit, at least one capacitor state of first capacitor pairs of the first switching circuit and at least one capacitor state of second capacitors pairs of the second switching circuit based on the outputs of the first comparator circuit and the second comparator circuit connected to the control circuit. The first and the second capacitor pairs are (e.g., respectively) arranged one after the other along the first voltage line and the second voltage line, and are (e.g., respectively) connected with a common node to the first voltage line and the second voltage line.

The method of the second aspect may correspond to the example embodiment of the ADC circuit of the first aspect. The method of the second aspect may be useful as described above with respect to the ADC circuit of the first aspect.

### BRIEF DESCRIPTION OF THE FIGURES

The above-described aspects and embodiments are provided in the following description with respect to the enclosed drawings:

FIG. 1 shows a comparator circuit according to this disclosure.

FIG. 2 shows an example diagram of a comparator circuit according to this disclosure.

FIG. 3 shows a schematic implementation of an example comparator circuit according to this disclosure.

FIGS. 4A, 4B, and 4C show simulation results of an example comparator circuit according to this disclosure and of a conventional comparator.

FIG. 5 illustrates an example comparator offset calibration method.

FIG. 6 shows an ADC circuit according to this disclosure.

FIGS. 7A and 7B illustrate state machines of main-switching and pre-switching control in an example ADC circuit according to this disclosure.

FIGS. 8A and 8B show a neural interface including an array of electrodes, a plurality of recording channels, and an ADC circuit according to this disclosure.

FIGS. 9A, 9B, 9C, and 9D illustrate transient waveforms of the example ADC circuit according to this disclosure.

FIG. 10 illustrates an example common-mode voltage generation method for an ADC circuit according to this disclosure.

FIG. 11 shows an example M-bit up-down counter of the ADC circuit according to this disclosure.

FIG. 12 shows a method of operating a comparator circuit according to this disclosure.

FIGS. 13A and 13B show a conventional LC ADC and some waveforms thereof.

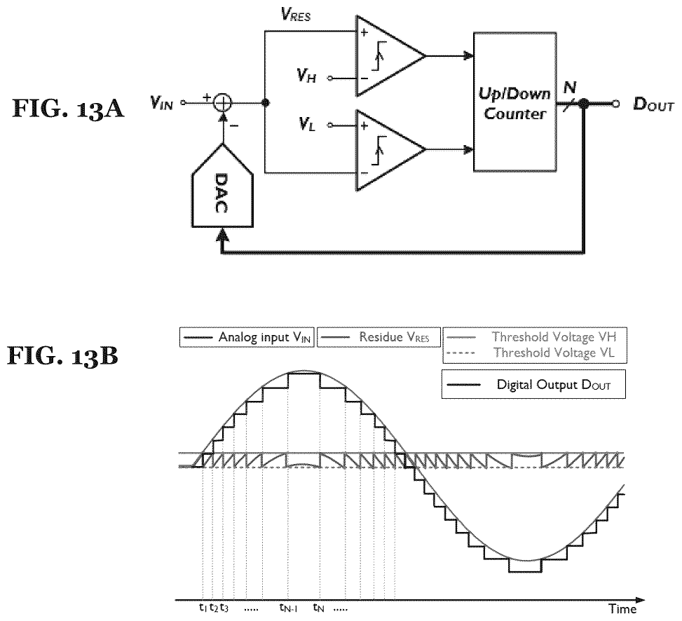

All the figures are schematic, not necessarily to scale, and generally show parts which elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

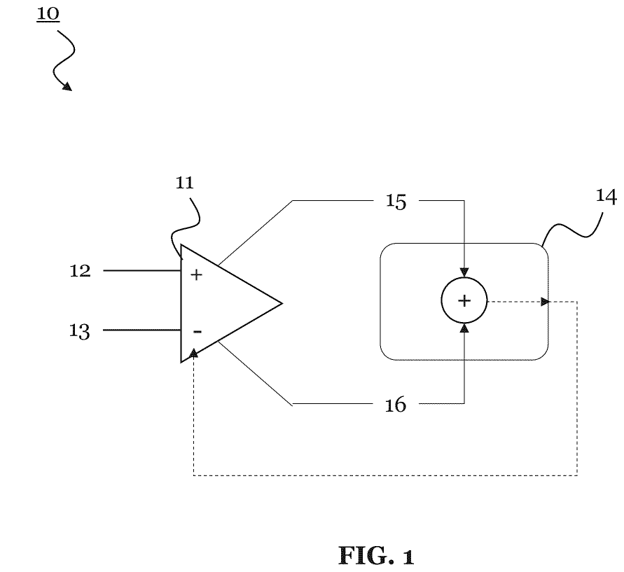

FIG. 1 shows a comparator circuit 10 according to this disclosure. The comparator circuit 10 comprises a comparator 11, which may be a conventional comparator having an inverting input and a non-inverting input. The comparator circuit 10 further comprises a bump bias circuit 14. The comparator circuit 10 may thus be referred to as a bump-based adaptive-bias comparator.

The comparator 11 is configured to receive a differential input signal, which comprises a first signal 12 and a second signal 13, for instance, two different voltage signals. At least one of these signals 12, 13 may be time-varying. The comparator 11 is configured to internally amplify the first signal 12 and the second signal 13, respectively, thereby producing an amplified first signal 15 and an amplified second signal 16.

The bump bias circuit 14 is connected to the comparator 11, for example, such that it is configured to receive the amplified first signal 15 and the amplified second signal 16, respectively, from the comparator 11. The bump bias circuit 14 may be configured to determine a difference between the amplified first signal 15 and the amplified second signal 16, for example, by summing the amplified first signal 15, which is associated with the non-inverting input of the comparator 11, and the amplified second signal 16, which is associated with the inverting input of the comparator 11.

The bump bias 14 circuit is further configured to cause the comparator 11 to operate at a higher power level when a difference between the amplified first signal 15 and the amplified second signal 16 is smaller, and to operate at a lower power level when the difference between the amplified first signal 15 and the amplified second signal 16 is larger. This may be done by providing a feedback signal to the comparator 11 (see dashed arrow in FIG. 1), which is dependent on the difference between the amplified first and second signals 15, 16. For example, the feedback signal may be a supply current. Since the comparator 11 is not (e.g., always) used in the higher power mode, but sometimes used in the lower power mode, its power consumption can be lowered. The comparator 11 may (e.g., only) operate in the higher power mode (e.g., when needed), such as in the case of an event expressed by the difference of the amplified signals 15, 16 becoming smaller.

In other words, to reduce the power consumption compared to a conventional comparator, the bump bias circuit 14 is integrated with the comparator 11. The bump bias circuit 14 is used to monitor the intermediate outputs, i.e., the amplified first and second signals 15, 16, which are the amplified versions of the input signals 12, 13 to the comparator 11.

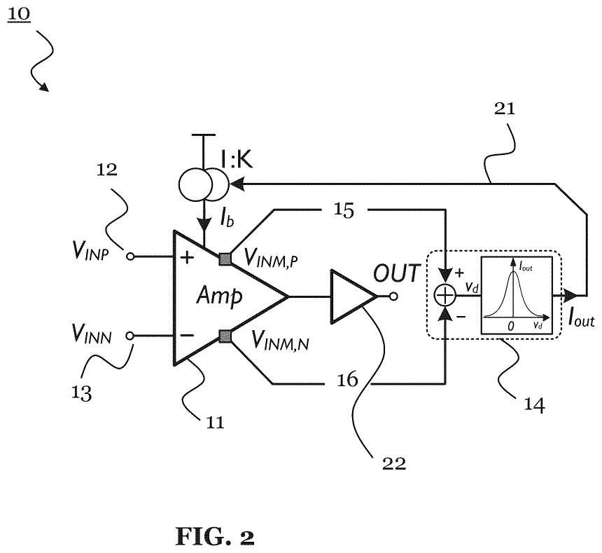

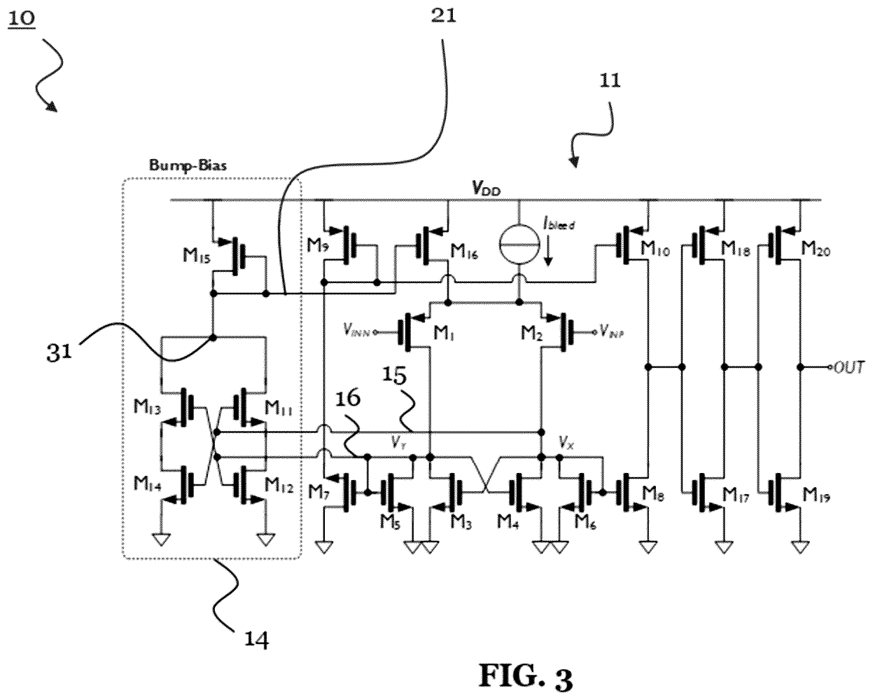

FIG. 2 shows an example diagram of a comparator circuit 10 according to this disclosure, and FIG. 3 shows a schematic implementation of an example comparator circuit 10 according to this disclosure. The comparator circuits 10 of FIGS. 2 and 3, respectively, are based on the comparator circuit 10 of FIG. 1. The same elements are labelled with the same reference signs and may be implemented likewise.

As shown in FIG. 2, the bump bias circuit 14 is, in this example, configured to provide a supply current as feedback signal to the comparator 11. For example, the bump bias circuit 14 is configured to provide a larger supply current 21 to the comparator 11 when the difference between the amplified first signal 15 and the amplified second signal 16 is smaller, and is configured to provide a smaller supply current 21 to the comparator 11 when the difference between the amplified first signal 15 and the amplified second signal 16 is larger. Given that the bump bias circuit 14 is calibrated, it may provide the largest supply current 21 to the comparator 11, if the amplified first signal 15 and the amplified second signal 16 are equal.

When the amplified signals 15 and 16 are closer together, the larger supply current will cause the comparator 11 to operate in the higher power mode, e.g., it may transition the comparator 11 into the higher power mode. Conversely, when the amplified signals 15 and 16 differ more from each other, the lower supply current will cause the comparator 11 to operate in the lower power mode, e.g., it may transition the comparator 11 to the lower power mode, in order to (e.g., significantly) save current and power.

The comparator 11 shown in FIG. 2 may also provide an output signal 22, like a conventional comparator without bump bias circuit 14.

As shown in FIG. 3, the bump bias circuit 14 may include four transistors M₁₁ to M₁₄ and an additional current output transistor M₁₅. The transistors M₁₁ to M₁₄ may be incorporated to monitor the intermediate output (e.g., amplified signals 15, 16 labelled V_{X} and V_{Y}) of the comparator 11. V_{X} and V_{Y} present the amplified versions of the input signals V_{INP} and V_{INN} shown in FIG. 2. The amplification may be related to a gain. The gain is expressed by g_{m1.2}/(g_{m5.6}−g_{m3.4}). When the amplified signals 15 and 16 related to the input signals 12 and 13 are close together, the larger supply current 21 is mirrored back through a current mirror to the comparator 11. The current mirror may be formed by Mis and a current input transistor M₁₆ of the comparator 11. The larger supply current 21 sets the comparator 11 to the higher power mode. The gate of Mis is thereby connected to the gate of M₁₆. When the amplified signals 15 and 16 related to the input signals 12 and 13 are more different from each other, the smaller supply current sets the comparator 11 to the lower power mode.

In an example embodiment, the first transistor M₁₁ and the second transistor M₁₂ form a first transistor pair, and the third transistor M₁₃ and the fourth transistor M₁₄ form a second transistor pair. A source of Mu is connected to a drain of M₁₂, and a source of M₁₃ is connected to a drain of M₁₄. Further, a source of M₁₂ and a source of M₁₄ are connected to ground. A drain of M₁₁ and a drain of M₁₃ are connected to a common node 31, to which also the current output transistor M₁₅ is connected. For example, a source of Mis may be connected to a supply voltage V_{DD}, a drain of M₁₅ may be connected to the common node 31, and a gate of M₁₅ may be connected to the drain of Mis and to the comparator 11.

The amplified first signal 15 (V_{X}) is connected to a gate of Mi and to a gate of M₁₄, and the amplified second signal 16 (V_{Y}) is connected to a gate of M₁₂ and to a gate of M₁₃. The current output transistor Mis is configured to output a larger supply current 21 to the comparator 11 when the difference between the amplified first signal 15 and the amplified second signal 16 is smaller, and to output a smaller supply current 21 to the comparator 11 when the difference between the amplified first signal 15 and the amplified second signal 16 is larger.

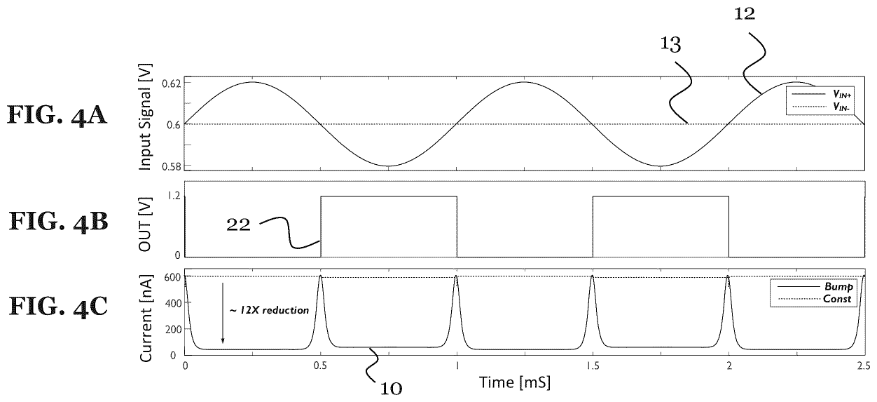

FIGS. 4A, 4B, and 4C show simulation results of the comparator circuit 10, including example input (voltage) signals 12 and 13 in FIG. 4A, an output signal 22 of the comparator in FIG. 4B, and a current consumption of the comparator 11—as compared to a conventional constant bias comparator—in FIG. 4C. As shown, the current consumption, and thus the power consumption, of the comparator 11 is reduced (e.g., significantly), up to a factor of 12 compared to the conventional comparator.

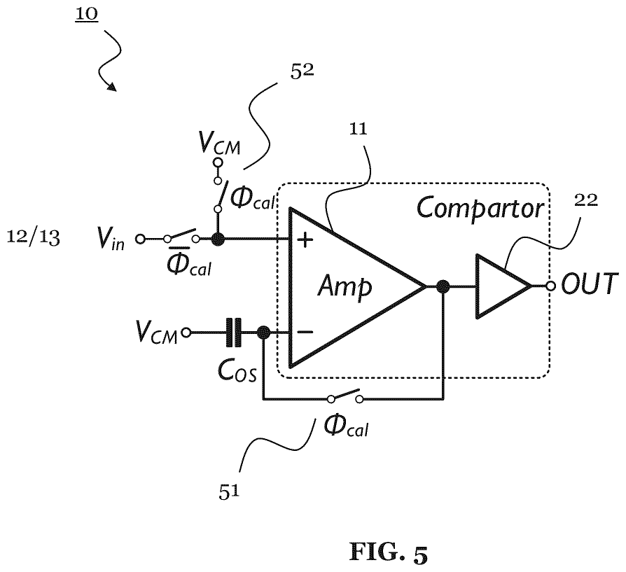

A mismatch across the transistors of the bump bias circuit 14 could introduce an offset, which could shift the zero-crossing point to an offset voltage Vos. That is, the largest supply current 21 would not be provided for the case when the first amplified signal 15 and the second amplified signal 16 are equal. However, to mitigate this effect, an offset calibration may be performed with the comparator circuit 10, before entering its normal ADC operations. An auto-zeroing technique can be used, as shown in FIG. 5. The auto-zeroing technique may guarantee the largest supply current 21 is provided for the case when the first amplified signal 15 and the second amplified signal 16 are equal.

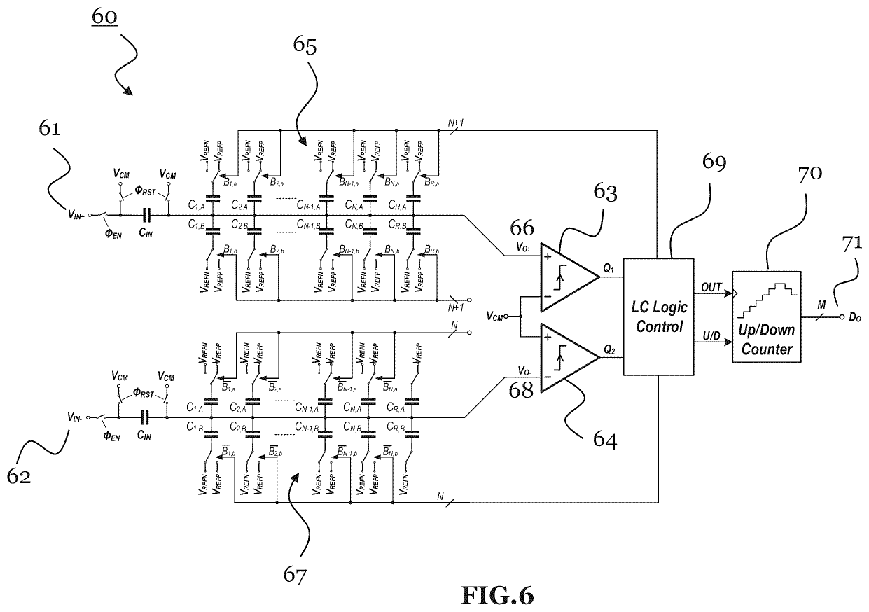

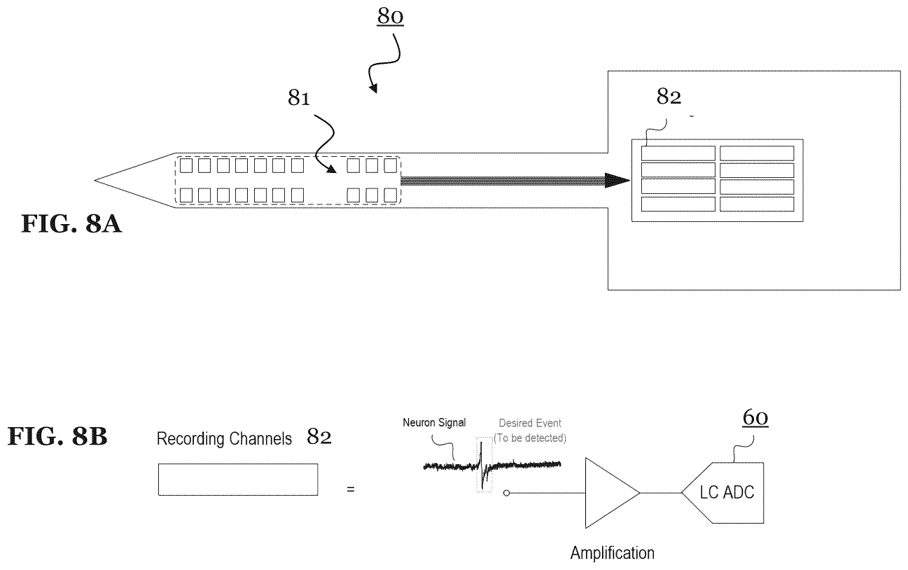

FIG. 6 shows an ADC circuit 60 according to this disclosure. The ADC circuit 60 may use the comparator circuit 10 presented above with respect to FIG. 1 or FIG. 2. That is, a beneficial application scenario for the comparator circuit 10 is presented. The ADC circuit 60 may be used for a neural interface 80, as shown in FIGS. 8A and 8B. In the neural interface 80, the ADC circuit 60 may periodically sample and convert neural signals, for example, for data transmission and post-processing.

FIG. 8A shows that the neural interface 80 may comprise a needle-like device, which may be equipped with an array of electrodes 81 connected to a plurality of recording channels 82. The use of the needle-like device may involve implanting the electrodes 81 to record or stimulate brain activity. The recording channels 82 may detect electrical signals from the neurons of the brain (i.e., the neural signals). Each recording channel 82 may record a (e.g., particular) neural signal, as shown in FIG. 8B. An event in the neural signal may be detected using the LC based ADC circuit 60 of FIG. 6.

The ADC circuit 60 may accordingly replace a conventional LC ADC, for example, in a neural interface 80. The ADC circuit 60 comprises a first switching circuit 65 and a second switching circuit 67, which may also be called pre-switching circuits, which are positioned (e.g., arranged) before a first comparator circuit 63 and a second comparator circuit 64 with relation to input and output. The ADC circuit 60 may thereby be provided with a built-in threshold-window switching mechanism. Either one or both of the first comparator circuit 63 and the second comparator circuit 64 may be implemented by a comparator circuit 10 as described with respect to FIG. 1 or FIG. 2, i.e., it may include a bump bias circuit 14. Alternatively, either one or both of the first comparator circuit 63 and the second comparator circuit 64 may be implemented by a simple comparator, in which case the respective comparator circuit 63, 64 does not comprise a bump bias circuit 14. In an example embodiment, the first and the second comparator circuit 63, 64 is (e.g., respectively) a comparator circuit 10 with a bump bias circuit 14. In another example embodiment, the first comparator circuit 63 is a comparator circuit 10 with a bump bias circuit 14, and the second comparator circuit 64 is a comparator without a bump bias circuit 14. In another example embodiment, the second comparator circuit 64 is a comparator circuit 10 with a bump bias circuit 14, and the first comparator circuit 63 is a comparator without a bump bias circuit 14. In another example embodiment, the first comparator circuit 63 and the second comparator circuit 64 is (e.g., respectively) a comparator without a bump bias circuit 14.

The first switching circuit 65 and the second switching circuit 67 are used to implement a pre-switching concept in the ADC circuit 60, in order to eliminate the use (e.g., need) of voltage thresholds, like in a conventional LC ADC.

The first switching circuit 65 is configured to receive a first signal 61, and to output a modified first signal 66 via a first voltage line to a non-inverting input of the first comparator circuit 63. The second switching circuit 67 is configured to receive a second signal 62 as an input, and to provide a modified second signal 68 via a second voltage line to an inverting input of the second comparator circuit 64. An inverting input of the first comparator circuit 63 and a non-inverting input of the second comparator circuit 64 are connected to a common mode voltage VCM of the first signal 61 and the second signal 62.

If the first comparator circuit 63 and the second comparator circuit 64 are comparator circuits 10, i.e. are integrated with a respective bump bias circuit 14, as described herein, then the differential input signal for the first comparator circuit 63 comprises the modified first signal 66 as the first signal 12, and comprises the common mode voltage as the second signal 13. The differential input signal for the second comparator circuit 64 comprises the modified second signal 68 as the second signal 13, and comprises the common mode voltage as the first signal 12.

The first switching circuit 65 comprises a plurality of first capacitor pairs, and the second switching circuit 67 comprises a plurality of second capacitor pairs (C_{i,A}, C_{i,B}). The first and the second capacitor pairs are (e.g., respectively) arranged one after the other along the first voltage line and the second voltage line, and are (e.g., respectively) connected with a common node to the first voltage line and the second voltage line.

An output of each comparator circuit 63, 64 (corresponding to the output signal 22 shown in FIG. 2 if implemented as the comparator circuit 10) is connected as input to a control circuit 69. The control circuit 69 is configured to set at least one capacitor state of the first capacitor pairs and at least one capacitor state of the second capacitors pairs based on the outputs of the first comparator circuit 63 and the second comparator circuit 64.

The pre-switching concept may be implemented by deviating the first signal 61 and the second signal 62 by a (e.g., certain) predetermined voltage value, which may be controlled by the control circuit 69. For example, by changing at least one capacitor state of the first capacitor pairs, a predetermined voltage value may be subtracted from the modified first signal 66 when the second signal 62 is smaller than the common mode voltage, and the predetermined voltage value may be added to the modified first signal 68 when the second signal 62 is larger than the common mode voltage.

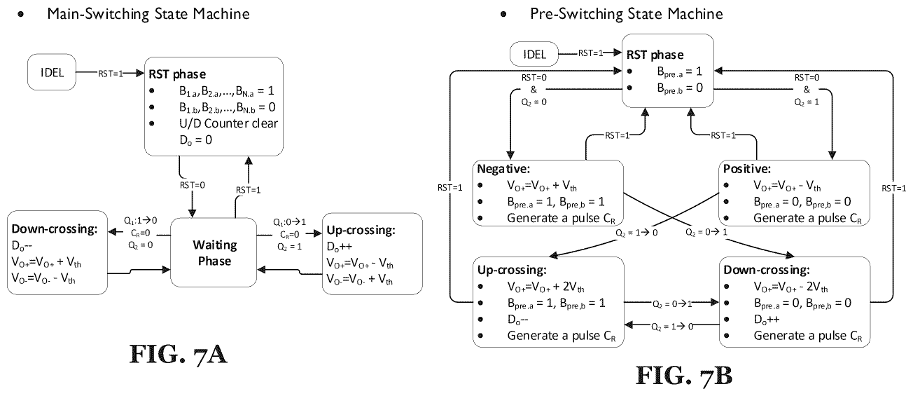

Additional example details of the ADC circuit 60 are described in the following with reference to FIG. 6 and FIGS. 7A and 7B. Here, the input signals 61 and 62 (V_{IN}+ and V_{IN}−) are differential signals with the common-mode voltage V_{CM}. As shown in FIG. 6, the ADC circuit 60 may have an M-bit resolution with 2×N (e.g., identical) capacitors (C_{i,A} and C_{i,B}, i=1 . . . . N) at each switching circuit 65, 67, wherein N=2^{(M-1)}−1. Two extra capacitors, C_{R,A} and C_{R,B}, may be added for an example of the pre-switching strategy at both switching circuits 65, 67. The input capacitor Cᵢₙ may be equal to the total capacitance of the control circuit 69.

A procedure, which may be performed by the ADC circuit 60, is provided with reference to FIGS. 7A and 7B, which shows a state machine of main-switching control in an example ADC circuit 60 (FIG. 7A) and pre-switching control in an example ADC circuit 60 (FIG. 7B) . . .

At a reset phase, the ADC control logic 69 initiates to a default value where all B_{1,a} . . . . B_{N,a}, B_{pre,a} and B_{1,b} . . . . B_{N,b}, B_{pre,b} bits are set to (N+1)′b11 . . . 11 and (N+1)′b00 . . . 00, respectively. Meanwhile, the differential voltage Vₒ₊ and Vₒ₋ at the top plate of the control circuit 69 are set to a common-mode voltage V_{CM}. Any of B_{1,a} . . . . B_{N,a}, B_{pre,a} and B_{1,b} . . . . B_{N,b} when set to 1, is connected to V_{REFN}, and when set to 0, is connected to V_{REFP}. The same holds for B_{r,a} and B_{r,b}, respectively.

After the reset phase, the second comparator circuit 64 will monitor the polarity of the voltage value of V_{CM}-V_{O} . . . . If the polarity is positive (V_{CM}>V_{O-}), the bit B_{pre,a} is changed from 1′b1 to 1′b0. Therefore, the certain value (predetermined voltage value) Vₜₕ will be subtracted from V_{O+}, which equals:

$${V}_{t h} = VDD \times \frac{{C}_{R , A}}{{C}_{i n} + {\sum }_{i = 1}^{N} {C}_{i , A} + {\sum }_{i = 1}^{N} {C}_{i , B} + {C}_{R , A} + {C}_{R , B}} = \frac{VDD}{4 N + 4}$$

If the polarity is negative (V_{CM}<V_{O-}), the bit B_{pre,b} is changed from 1′b0 to 1′b1, and Vₜₕ will be added to V_{O+}.

The first comparator circuit 63 (e.g., continuously) monitors the voltage V_{O+} and compares it to the common-mode voltage V_{CM}.

If an up-crossing (Q₁:0→1 while Q₂=1) happens—i.e., when the output of the first comparator circuit 63 switches “up” from a low state to a high state, while the output of the second comparator circuit 64 stays at a high state—the bit Bia changes from 1′b1 to 1′b0, subtracting the predetermined voltage value Vₜₕ from the modified first signal V_{O+} and adding the predetermined voltage value Vₜₕ to the modified second signal V_{O-} respectively.

If a down-crossing (Q₁:1→0 while Q₂=0) happens—i.e., when the output of the first comparator circuit 63 switches “down” from a high state to a low state, while the output of the second comparator circuit 64 stays at a low state—the bit B_{i,b} changes from 1′b0 to 1′b1, adding the predetermined voltage value Vₜₕ to the modified first signal V_{O+} and subtracting the predetermined voltage value Vₜₕ from the modified second signal V_{O-} respectively. The output of the ADC is cumulated by Dₒ=Dₒ−1.

The second comparator circuit 64 monitors the voltage V_{O-} and compares it to the common-mode voltage V_{CM}.

If an up-crossing (Q₂:1→0) happens—i.e., when the output of the second comparator circuit 64 switches “down” from a high state to a low state—the bit B_{pre,a} and B_{pre,b} both change from 1′b0 to 1′b1, a value of twice the predetermined voltage value 2× Vₜₕ will be added to the modified first signal V_{O+}. The output of the ADC is cumulated by Dₒ=Dₒ−1.

If a down-crossing (Q₂:0→1) happens—i.e., when the output of the second comparator circuit 64 switches “up” from a low state to a high state—the bit B_{pre,a} and B_{pre,b} both change from 1′b1 to 1′b0, a value of twice the predetermined voltage value 2× Vₜₕ will be subtracted from the modified first signal V_{O+}. The output of the ADC is cumulated by Dₒ=Dₒ+1.

Steps, such as steps 2 to 4, may be repeated until a reset is activated or the output of the ADC circuit 60 is overflowed.

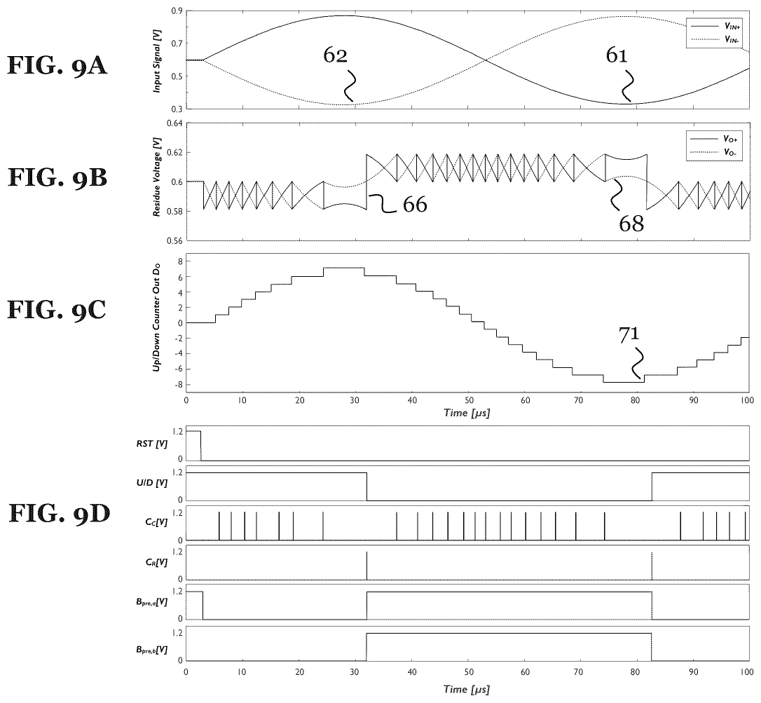

FIGS. 9A-9D shows transient waveforms of the example ADC circuit 60 according to this disclosure. For example, FIG. 9A shows the first and second signal 61, 62, while FIG. 9B shows the modified signals 66, 68. The output 71 provided by the up-down counter 70 is shown in FIG. 9C, and FIG. 9D illustrates some internal parameters of the ADC circuit 60.

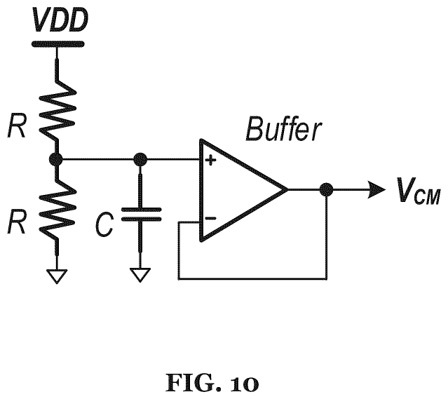

As further shown in FIG. 10, the common-mode voltage V_{CM} can be generated globally with a division ratio of 0.5 from the supply voltage V_{DD} by a resistive divider. Notice that unlike the threshold voltage V_{H} and V_{L} in a conventional LC ADC, the common-mode voltage V_{cM} can be shared across recording channels and the ADC circuit 60. The noise of the V_{CM} can be filtered out by a simple RC filter to minimize its impact on the comparator decision.

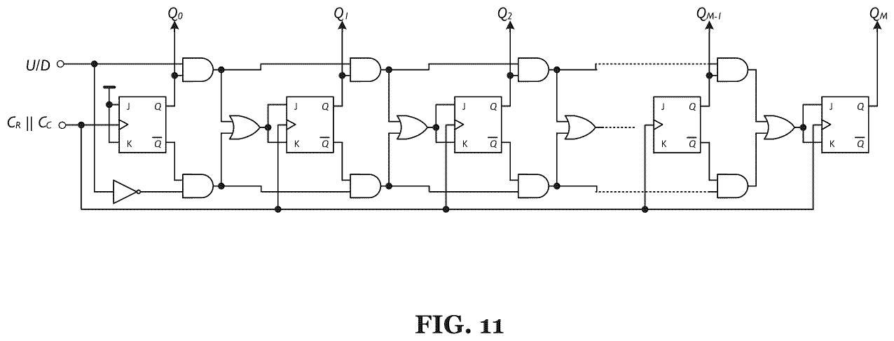

As further shown in FIG. 11, the (M-bit) up-down counter 70 of the ADC circuit 60 can be implemented using multiple JK flip-flops.

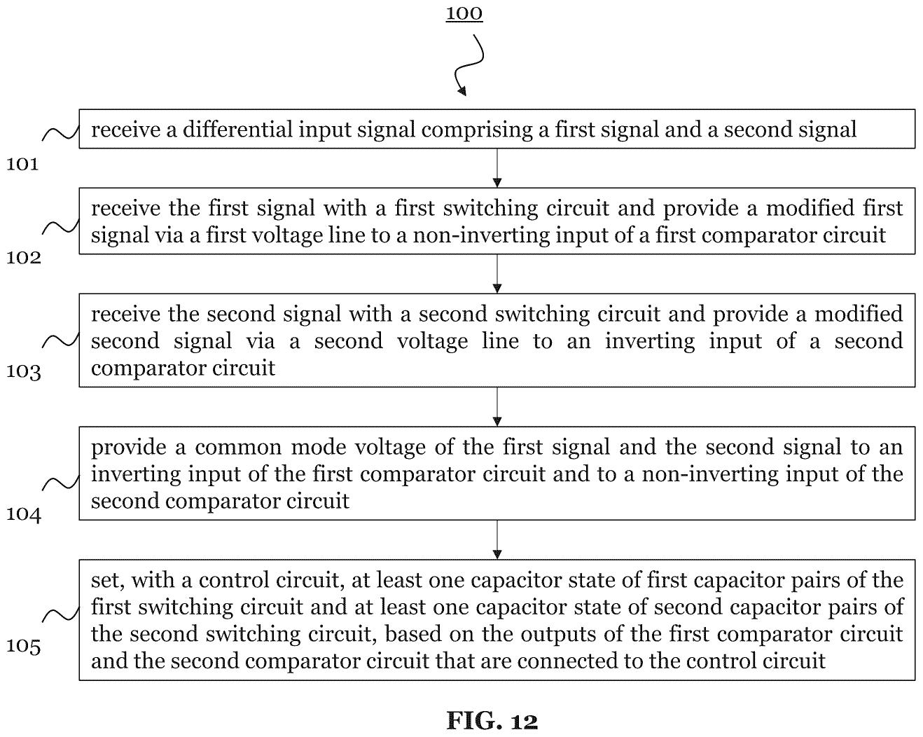

FIG. 12 shows a method 100 of operating an ADC circuit 60 according to this disclosure, wherein the ADC circuit 60 comprises a first comparator circuit 63, a second comparator circuit 64, a first switching circuit 65, a second switching circuit 67, and a control circuit 69, as shown in FIG. 6. The first comparator circuit 63 and/or the second comparator circuit 64 may be a comparator circuit 10 as shown in FIG. 1 or FIG. 2, and may accordingly comprise the bump bias circuit 14.

The method 100 comprises a step 101 of receiving a differential input signal, which comprises a first signal and a second signal, e.g., with a general input of the ADC circuit 60. The method 100 may further comprise a step 102 of receiving the first signal 61 with the first switching circuit 65 and providing a modified first signal 66 via a first voltage line from the first switching circuit 65 to a non-inverting input of the first comparator circuit 63, and a step 103 of receiving the second signal 62 with the second switching circuit 65 and providing a modified second signal 68 via a second voltage line from the second switching circuit 67 to an inverting input of the second comparator circuit 63. The method 100 also comprises a step 104 of providing a common mode voltage of the first signal and the second signal to an inverting input of the first comparator circuit 63 and to a non-inverting input of the second comparator circuit 64, respectively. Further, the method 100 comprises a step 105 of setting, by the control circuit 69, at least one capacitor state of first capacitor pairs of the first switching circuit 65 and at least one capacitor state of second capacitors pairs of the second switching circuit 67, based on the outputs of the first comparator circuit 63 and the second comparator circuit 64, which are connected to the control circuit 69. The first and the second capacitor pairs are respectively arranged one after the other along the first voltage line and the second voltage line, and are respectively connected with a common node to the first voltage line and the second voltage line.

In sum, this disclosure may eliminate the use of the external threshold voltages V_{H} and V_{L} as used (e.g., required) in a conventional LC ADC. The ADC circuit 60 using the control circuit 69 generates the threshold window, hence, avoiding the mismatch between the threshold and feedback value Vₜₕ. Moreover, the bump-based adaptive-bias comparator circuit 10 may (e.g., efficiently) reduce a power consumption compared to the conventional continuous-time comparator. This is, because it consumes power (e.g., only) when the differential input is close to each other.

The improvements in this disclosure may be applied within high-density neural recording systems, such as for data compression, resulting in a substantial reduction in data throughput specifications (e.g., requirements) for high-density neural probes (e.g., Neuropixels 1.0, 2.0 and NXT).

Herein, the word “comprising” does not exclude other elements or steps and the indefinite article “a” or “an” does not exclude a plurality. A single element may fulfill the functions of several entities or items recited in the claims. The mere fact that certain measures are recited in the mutual different dependent claims does not indicate that a combination of these measures cannot be used in another implementation.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. An analog to digital converter (ADC) circuit for a neural interface, wherein the ADC circuit is configured to receive a differential input signal comprising a first signal and a second signal, and wherein the ADC circuit comprises:
a first comparator circuit and a second comparator circuit, wherein an inverting input of the first comparator circuit and a non-inverting input of the second comparator circuit are connected to a common mode voltage of the first signal and the second signal;
a first switching circuit configured to receive the first signal and to provide a modified first signal via a first voltage line to a non-inverting input of the first comparator circuit;
a second switching circuit configured to receive the second signal as an input and to provide a modified second signal via a second voltage line to an inverting input of the second comparator circuit; and
a control circuit, wherein an output of the first comparator circuit and the second comparator circuit is connected as input to the control circuit, and an output of the second comparator circuit is connected as input to the control circuit;
wherein the first switching circuit comprises a plurality of first capacitor pairs, and the second switching circuit comprises a plurality of second capacitor pairs, wherein the first and the second capacitor pairs are respectively arranged along the first voltage line and the second voltage line, and are respectively connected with a common node to the first voltage line and the second voltage line; and
wherein the control circuit is configured to set at least one capacitor state of the first capacitor pairs and at least one capacitor state of the second capacitors pairs based on the output of the first comparator circuit and based on the output of the second comparator circuit.

2. The ADC circuit according to claim 1, wherein the control circuit is configured to initially set each capacitor state to a default value.

3. The ADC circuit according to claim 1, wherein the control circuit is configured to
change at least one capacitor state of the first capacitor pairs, such that a predetermined voltage value is subtracted from the modified first signal when the second signal is smaller than the common mode voltage, and such that the predetermined voltage value is added to the modified first signal when the second signal is larger than the common mode voltage.

4. The ADC circuit according to claim 3, wherein
when the output of the first comparator circuit switches up from a low state to a high state, while the output of the second comparator circuit stays at a high state, the control circuit is configured to change at least one capacitor state of the first capacitor pairs such that the predetermined voltage value is subtracted from the modified first signal, and to change at least one capacitor state of the second capacitor pair such that the predetermined voltage value is added to the modified second signal.

5. The ADC circuit according to claim 4, wherein
when the output of the first comparator circuit switches down from a high state to a low state, while the output of the second comparator circuit stays at a low state, the control circuit is configured to change at least one capacitor state of the first capacitor pairs such that the predetermined voltage value is added to the modified first signal, and to change at least one capacitor state of the second capacitor pairs such that the predetermined voltage value is subtracted from the modified second signal.

6. The ADC circuit according to claim 3, wherein
when the output of the second comparator circuit switches down from a high state to a low state, the control circuit is configured to change at least one capacitor state of the first capacitor pairs such that twice the predetermined voltage value is added to the modified first signal.

7. The ADC circuit according to claim 6, wherein
when the output of the second comparator circuit switches up from a low state to a high state, the control circuit is configured to change at least one capacitor state of the first capacitor pairs such that twice the predetermined voltage value is subtracted from the modified first signal.

8. The ADC circuit according to claim 4, further comprising
an up-down counter, which is configured to receive from the control circuit an output signal and an indication of an up switch or a down switch of a comparator circuit output, and is configured to output a cumulated signal based on the output signal and the indication received from the control circuit.

9. The ADC circuit according to claim 1, wherein the first comparator circuit comprises:
a first comparator configured to internally amplify the modified first signal and the common mode voltage; and
a first bump bias circuit configured to receive the amplified modified first signal and the amplified common mode voltage.

10. The ADC circuit according to claim 9, wherein the first bump bias circuit is further configured to cause the first comparator to:
operate at a higher power level when a difference between the amplified modified first signal and the amplified common mode voltage is smaller; and
operate at a lower power level when the difference between the amplified modified first signal and the amplified common mode voltage is larger.

11. The ADC circuit according to claim 9, wherein the second comparator circuit comprises:
a second comparator configured to internally amplify the modified second signal and the common mode voltage; and
a second bump bias circuit configured to receive the amplified modified second signal and the amplified common mode voltage.

12. The ADC circuit according to claim 11, wherein the second bump bias circuit is further configured to cause the second comparator to:
operate at a higher power level when a difference between the amplified modified second signal and the amplified common mode voltage is smaller; and
operate at a lower power level when the difference between the amplified modified second signal and the amplified common mode voltage is larger.

13. The ADC circuit according to claim 11, wherein the first bump bias circuit or the second bump bias circuit is configured to provide a larger supply current to the first or second comparator when the difference between the amplified modified first or second signal and the amplified common mode voltage is smaller.

14. The ADC circuit according to claim 13, wherein the first bump bias circuit or the second bump bias circuit is configured to provide a smaller supply current to the first or second comparator when the difference between the amplified modified first or second signal and the amplified common mode voltage is larger.

15. The ADC circuit according to claim 9, wherein the first bump bias circuit or the second bump bias circuit is configured to provide an increasing supply current to the first or second comparator when a difference between the amplified modified first or second signal and the amplified common mode voltage decreases.

16. The ADC circuit according to claim 9, wherein the first bump bias circuit or the second bump bias circuit comprises:
a first transistor pair comprising a first transistor and a second transistor;
a second transistor pair comprising a third transistor and a fourth transistor, wherein a source of the first transistor is connected to a drain of the second transistor;
wherein a source of the third transistor is connected to a drain of the fourth transistor;
wherein a source of the second transistor and a source of the fourth transistor are connected to ground;
wherein a drain of the first transistor and a drain of the third transistor are connected to a common node, to which also a current output transistor is connected;
wherein the amplified modified first signal or second signal is connected to a gate of the first transistor and a gate of the fourth transistor;
wherein the amplified common mode voltage is connected to a gate of the second transistor and a gate of the third transistor; and
wherein the current output transistor is configured to output a larger supply current to the first comparator or second comparator when the difference between the amplified modified first signal or second signal and the amplified common mode voltage is smaller, and output a smaller supply current to the first or second comparator when the difference between respectively the amplified modified first or second signal and the amplified common mode voltage is larger.

17. The ADC circuit according to claim 16, wherein
a source of the current output transistor is connected to a supply voltage;
a drain of the current output transistor is connected to the common node; and
a gate of the current output transistor is connected to the drain of the current output transistor and to the first comparator or second comparator.

18. The ADC circuit according to claim 16, wherein the gate of the current output transistor is connected to a gate of a current input transistor of the first comparator or second comparator, and wherein the current output transistor and the current input transistor form a current mirror.

19. The ADC circuit according to claim 9, wherein the first or second comparator circuit is configured to
perform an auto-zeroing operation to calibrate the first bump bias circuit or second bump bias circuit, such that the first bump bias circuit or second bump bias circuit is configured to cause the first or second comparator to operate at a maximum power level when the amplified modified first or second signal is equal to the amplified common mode voltage.

20. A method of operating an analog to digital converter (ADC) circuit for a neural interface, wherein the ADC circuit comprises a first comparator circuit, a second comparator circuit, a first switching circuit, a second switching circuit, and a control circuit, and wherein the method comprises:
receiving a differential input signal comprising a first signal and a second signal;
receiving the first signal with the first switching circuit and providing a modified first signal via a first voltage line to a non-inverting input of the first comparator circuit;
receiving the second signal with the second switching circuit and providing a modified second signal via a second voltage line to an inverting input of the second comparator circuit;
providing a common mode voltage of the first signal and the second signal to an inverting input of the first comparator circuit and to a non-inverting input of the second comparator circuit; and
setting, by the control circuit, at least one capacitor state of first capacitor pairs of the first switching circuit and at least one capacitor state of second capacitor pairs of the second switching circuit based on an output of the first comparator circuit and an output of the second comparator circuit connected to the control circuit,
wherein the first and the second capacitor pairs are respectively arranged along the first voltage line and the second voltage line and are respectively connected with a common node to the first voltage line and the second voltage line.
